(19) United States
(12) Patent Application Publication
(10) Pub. No.: US 2026/0047398 A1
(43) Pub. Date: Feb. 12, 2026

(54) SEMICONDUCTOR TEST STRUCTURE

(71) Applicant: United Microelectronics Corp., Hsinchu (TW)

(72) Inventors: Jih-Shun CHIANG, Hsinchu City (TW); Tzu-Jun CHEN, Hsinchu City (TW); Wen-Hsiung KO, Taichung City (TW); Wen-Chun CHANG, Hsinchu City (TW); Sung-Nien KUO, Hsinchu City (TW); Kuan-Cheng SU, Hsinchu City (TW)

(21) Appl. No.: 18/827,907

(22) Filed: Sep. 9, 2024

(30) Foreign Application Priority Data
Aug. 6, 2024 (TW) 113129356

(51) Int. Cl. H01L 21/66

(52) U.S. Cl. CPC H01L 22/32

(57) ABSTRACT

A semiconductor test structure includes a substrate, a first gate structure and a second gate structure, a first conductive layer and an air gap. The first gate structure and the second gate structure are stacked on the substrate along a first direction, extend along a second direction and are spaced apart from each other along a third direction. The first conductive layer is stacked on the substrate and includes a first electrode and a second electrode. The first electrode extends along the second direction, and at least a portion of the second electrode extends along the second direction. A region of the air gap projected on the substrate along the first direction is between regions of the first gate structure and the second gate structure projected on the substrate along the first direction.

This application claims the benefit of Taiwan application Serial No. 113129356, filed Aug. 6, 2024, the subject matter of which is incorporated herein by reference.

### BACKGROUND OF THE INVENTION

### Field of the Invention

The invention relates in general to a test structure, and more particularly to a semiconductor test structure.

### Description of the Related Art

Generally speaking, semiconductor devices include in-line semiconductor testing structures to monitor whether the products of the semiconductor devices meet expected specifications. For example, the semiconductor test structure may include a gate structure, which may be disposed below conductive interconnects formed in a back-end-of-line (BEOL) process and multiple dielectric layers surrounding the conductive interconnects. When the gate structure is in operation, it can generate a large amount of heat, such as Joule heating effect. Therefore, this gate structure can be used as a heater for reliability testing of semiconductor devices.

In some semiconductor devices produced by the advanced process, there is a higher demand for capacitance reduction. However, the current semiconductor test structure cannot meet the requirements of these semiconductor devices produced by the advanced process.

### SUMMARY OF THE INVENTION

The invention is directed to a semiconductor test structure. The semiconductor test structure includes an air gap. Therefore, the semiconductor test structure according to the present application can have lower capacitance in comparison with a semiconductor test structure without an air gap, and can meet the requirements of the semiconductor devices produced by the advanced process.

According to an embodiment of the present invention, a semiconductor test structure is provided. The semiconductor test structure includes a substrate, a first gate structure and a second gate structure, a first conductive layer and at least one air gap. The first gate structure and the second gate structure are stacked on the substrate along a first direction, respectively extend along a second direction and are spaced apart from each other along a third direction. The first direction, the second direction and the third direction are different from each other. The first conductive layer is stacked on the substrate along the first direction and includes a first electrode and a second electrode. The first electrode extends along the second direction, and at least a portion of the second electrode extends along the second direction. The air gap is stacked on the substrate along the first direction and extends along the second direction. The air gap is disposed between the first electrode and the second electrode. A region of the air gap projected on the substrate along the first direction is between regions of the first gate structure and the second gate structure projected on the substrate along the first direction.

According to another embodiment of the present invention, a semiconductor test structure is provided. The semiconductor test structure includes a substrate, a first gate structure and a second gate structure, a first conductive layer and a plurality of air gaps. The first gate structure and the second gate structure are stacked on the substrate along a first direction, respectively extend along a second direction and are spaced apart from each other along a third direction. The first direction, the second direction and the third direction are different from each other. The first conductive layer is stacked on the substrate along the first direction and includes a first electrode, a second electrode and a third electrode spaced apart from each other. The air gaps are stacked on the substrate along the first direction and extends along the third direction, respectively. The air gap is disposed between the first electrode, the second electrode and the third electrode. Regions of the air gaps projected on the substrate along the first direction is between regions of the first gate structure and the second gate structure projected on the substrate along the first direction.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1A shows a top view of a semiconductor test structure according to an embodiment of the present invention.

FIG. 1B shows a cross-sectional view taken along line 1B-1B′ of FIG. 1A.

FIG. 2A shows a top view of a semiconductor test structure according to another embodiment of the present invention.

FIG. 2B shows a cross-sectional view taken along line 2B-2B′ of FIG. 2A.

FIG. 2C shows a cross-sectional view taken along line 2C-2C′ of FIG. 2A.

### DETAILED DESCRIPTION OF THE INVENTION

The following is illustrated with some examples. It should be noted that the present invention does not show all possible embodiments, and other implementation aspects not proposed in the present invention may also be applicable. Furthermore, the size ratios in the drawings are not drawn to the same proportions as the actual product. Therefore, the description and drawings are only used to describe the embodiments and are not used to limit the scope of the present invention. In addition, the descriptions in the embodiments, such as detailed structures, material applications, etc., are only for illustration and do not limit the scope of the present invention. The structural details of the embodiments can be changed and modified according to the needs of the actual application process without departing from the spirit and scope of the present invention. The following description uses the same/similar symbols to indicate the same/similar components. It is understood that elements and features of one embodiment may be advantageously incorporated into another embodiment without further recitation.

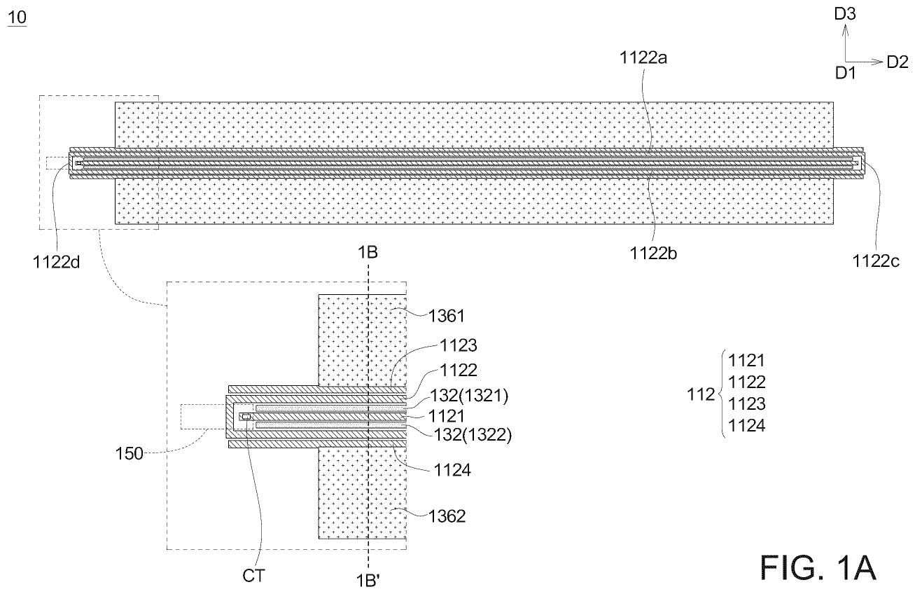

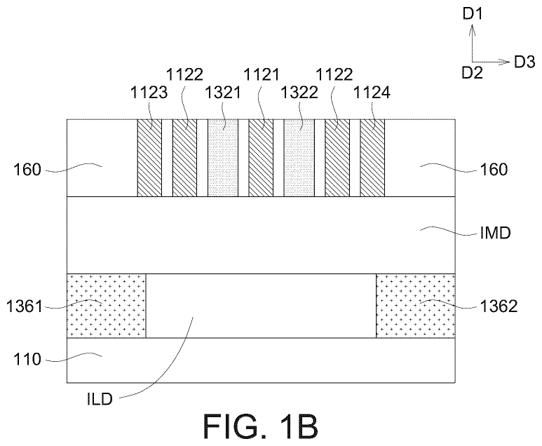

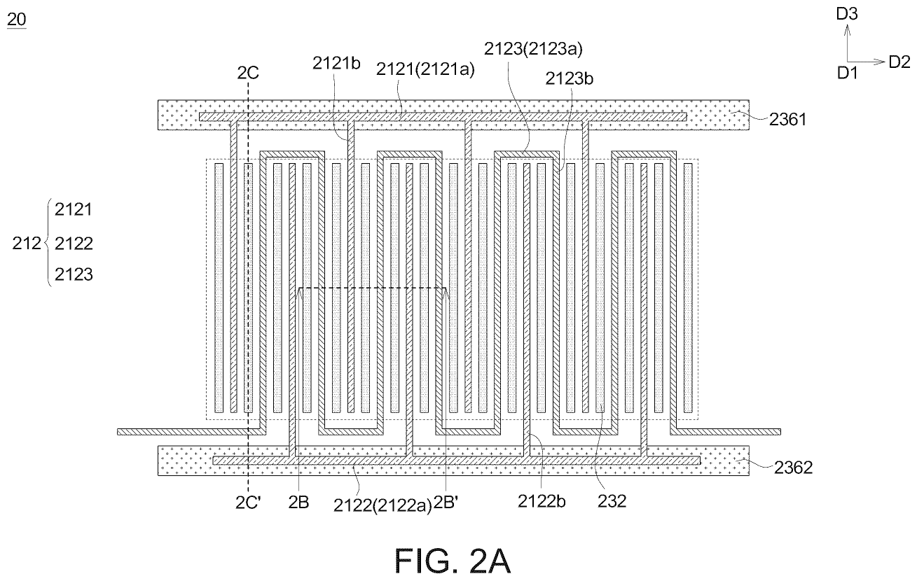

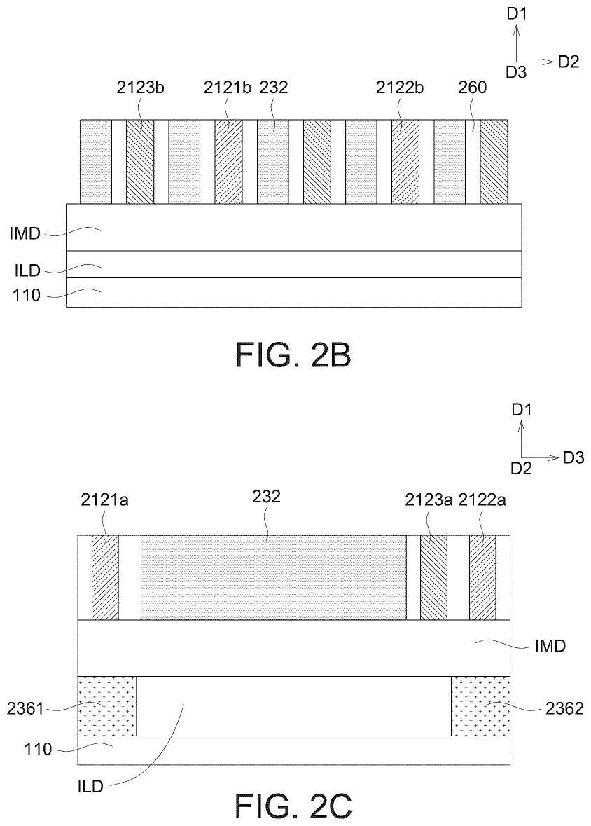

In some semiconductor devices produced by the advanced process, capacitance can be reduced by forming an air gap in the dielectric layer between conductive interconnects. However, the manufacturing process for arranging the entire gate structure as a heater in the semiconductor test structure will conflict with the manufacturing process for the air gap. Therefore, the present invention redesigns the gate structure (for example, the first gate structure 1361 and the second gate structure 1362 shown in FIGS. 1A to 1B, as well as the first gate structure 2361 and the second gate structure 2362 shown in FIGS. 2A and 2C), to meet the requirements for forming the air gap. In other words, the semiconductor device (for example, produced by the advanced process) includes an in-line semiconductor test structure 10 or 20.

FIG. 1A shows a top view of a semiconductor test structure 10 according to an embodiment of the present invention. FIG. 1B shows a cross-sectional view taken along line 1B-1B′ of FIG. 1A. FIG. 2A shows a top view of a semiconductor test structure 20 according to another embodiment of the present invention. FIG. 2B shows a cross-sectional view taken along the line 2B-2B′ of FIG. 2A. FIG. 2C shows a cross-sectional view taken along the line 2C-2C′ of FIG. 2A.

Referring to FIGS. 1A-1B, the semiconductor test structure 10 includes a substrate 110, a first gate structure 1361 and a second gate structure 1362, a first conductive layer 112 and at least one air gap 132. The first gate structure 1361 and the second gate structure 1362 are stacked on the substrate 110 along a first direction D1. The first gate structure 1361 and the second gate structure 1362 respectively extend along a second direction D2, and are spaced apart from each other along a third direction D3. The first direction D1, the second direction D2 and the third direction D3 are different from each other. for example, first direction D1, the second direction D2 and the third direction D3 are perpendicular to each other, but the invention is not limited thereto. That is, the first gate structure 1361 and the second gate structure 1362 are separated from each other and have no contact. The materials of the first gate structure 1361 and the second gate structure 1362 include polysilicon, and the first gate structure 1361 and the second gate structure 1362 can act as resistors. By applying current to the first gate structure 1361 and the second gate structure 1362, heat energy can be generated, thereby heating the semiconductor test structure 10, so as to facilitate a reliability testing, such as Electron Migration (EM) reliability testing. A lower dielectric layer ILD is disposed between the first gate structure 1361 and the second gate structure 1362, and the first gate structure 1361 and the second gate structure 1362 are separated by the lower dielectric layer ILD.

The first conductive layer 112 is stacked on the substrate 110 along the first direction D1. At least a portion of the first conductive layer 112 does not overlap the first gate structure 1361 and the second gate structure 1362 in the first direction D1. In the present embodiment, the first conductive layer 112 includes a first electrode 1121, a second electrode 1122, a third electrode 1123, and a fourth electrode 1124, but the invention is not limited thereto. The first electrode 1121 extends along the second direction D2, and at least a portion of the second electrode 1122 extends along the second direction D2. Furthermore, the second electrode 1122 includes two first portions 1122a-1122b extending along the second direction D2 and two second portions 1122c-1122d extending along the third direction D3. The two first portions 1122a-1122b are spaced apart from each other along the third direction D3. The two second portions 1121c-1121d are spaced apart from each other along the second direction D2. The two first portions 1122a-1122b are connected to the two second portions 1122c-1122d to form the second electrode 1122 which is a closed structure. The second electrode 1122 may surround the first electrode 1121. The third electrode 1123 and the fourth electrode 1124 may be disposed on opposite sides of the second electrode 1122. At least a portion of the first conductive layer 112 does not overlap the first gate structure 1361 and the second gate structure 1362 in the first direction D1.

According to the present embodiment, the first conductive layer 112 may partially overlap the first gate structure 1361 and the second gate structure 1362 in the first direction D1. For example, a portion of the third electrode 1123 may partially overlap the first gate structure 1361 in the first direction D1, and a portion of the fourth electrode 1124 may partially overlap the second gate structure 1362 in the first direction D1.

As shown in FIG. 1B, the air gaps 132 overlaps at least a portion of the first conductive layer 112 (i.e., including the first electrode 1121, the second electrode 1122, the third electrode 1123 and the fourth electrode 1124) in the third direction D3. Please refer to FIGS. 1A and 1B at the same time. The air gaps 132 are stacked on the substrate 110 along the first direction D1 and extends along the second direction D2. The air gaps 132 are disposed between the first electrode 1121 and the second electrode 1122. In the present embodiment, the number of air gaps 132 is two, that is, the air gaps 132 includes a first air gap 1321 and a second air gap 1322, but the invention is not limited thereto. The first air gap 1321 and the second air gap 1322 are spaced apart from each other along the third direction D3 and are disposed on opposite sides of the first electrode 1121. The second electrode 1122 surrounds the first air gap 1321, the first electrode 1121 and the second air gap 1322. The first electrode 1121 to the fourth electrode 1124 and the first air gap 1321 and the second air gap 1322 are separated by, for example, a dielectric material 160. Regions of the air gaps 132 projected on the substrate 110 along the first direction D1 (for example, the vertical direction) is disposed between regions of the first gate structure 1361 and the second gate structure 1362 projected on the substrate 110 along the first direction D1 (for example, the vertical direction). In other words, the air gaps 132 may not overlap the first gate structure 1361 and the second gate structure 1362 in the first direction D1.

According to the present embodiment, the semiconductor test structure 10 may further include an intermediate dielectric layer IMD. The intermediate dielectric layer IMD covers the first gate structure 1361, the second gate structure 1362 and the lower dielectric layer ILD, and is disposed between the first gate structure 1361, the second gate structure 1362 and the first conductive layer 112. That is, the air gaps 132 and the first conductive layer 112 may be disposed on the intermediate dielectric layer IMD. In some embodiments, the lower dielectric layer ILD, the intermediate dielectric layer

IMD, and the dielectric material 160 may be formed of the same material, or may be formed of different materials.

The semiconductor test structure 10 may further include a diffusion layer 150 and a contact structure CT. The contact structure CT and the diffusion layer 150 are sequentially stacked on the substrate 110 along the first direction D1, wherein the first electrode 1121, the contact structure CT and the diffusion layer 150 are electrically connected. Furthermore, the diffusion layer 150 connects the contact structure CT and the first electrode 1121.

Referring to FIGS. 2A to 2C, the semiconductor test structure 20 includes a substrate 110, a first gate structure 2361, a second gate structure 2362, a first conductive layer 212 and a plurality of air gaps 232. The first gate structure 2361 and the second gate structure 2362 are stacked on the substrate 110 along a first direction D1. The first gate structure 2361 and the second gate structure 2362 respectively extend along a second direction D2, and are spaced apart from each other along a third direction D3. The first direction D1, the second direction D2 and the third direction D3 are different from each other. For example, the first direction D1, the second direction D2 and the third direction D3 are perpendicular to each other, but the invention is not limited thereto. The materials of the first gate structure 2361 and the second gate structure 2362 include polysilicon, and the first gate structure 2361 and the second gate structure 2362 can act as resistors. By applying current to the first gate structure 2361 and the second gate structure 2362, heat energy can be generated, thereby heating the semiconductor test structure 20, so as to facilitate the reliability testing, such as inter-metal dielectric (IMD) reliability testing. A lower dielectric layer ILD is disposed between the first gate structure 2361 and the second gate structure 2362, and the first gate structure 2361 and the second gate structure 2362 are separated by the lower dielectric layer ILD.

The first conductive layer 212 is stacked on the substrate 110 along the first direction D1, and at least a portion of the first conductive layer 212 does not overlap the first gate structure 2361 and the second gate structure 2362 in the first direction D1. In the present embodiment, the first conductive layer 212 includes a first electrode 2121, a second electrode 2122 and a third electrode 2123 that are spaced apart from each other. The first electrode 2121 includes a first main body portion 2121a and a plurality of first branch portions 2121b connected to the first main body portion 2121a. The first branch portions 2121b are spaced apart from each other. The second electrode 2122 includes a second main body portion 2122a and a plurality of second branch portions 2122b connected to the second main body portion 2122a. The second branch portions 2122b are spaced apart from each other. The third electrode 2123 includes a plurality of third main body portions 2123a and a plurality of third branch portions 2123b connected to the third main body portion 2123a. The first main body portion 2121a, the second main body portion 2122a and the third main body portion 2123a extend along the second direction D2, respectively. The first branch portions 2121b, the second branch portions 2122b and the third branch portions 2123b extend along the third direction D3, respectively. A portion of the first conductive layer 212 may overlap the first gate structure 2361 and the second gate structure 2362 in the first direction D1. For example, the first body portion 2121a of the first electrode 2121 may overlap the first gate structure 2361 in the first direction D1, and the second body portion 2122a of the second electrode 2122 may overlap the second gate structure 2362 in the first direction D1. The first electrode 2121 and the second electrode 2122 are similar to a pair of comb-shaped electrodes and can be electrically connected to each other (not shown). The first electrode 2121 and the second electrode 2122 are not electrically connected to the third electrode 2123. The third electrode 2123 is similar to an S-shaped electrode and serpentines between the first electrode 2121 and the second electrode 2122.

The air gaps 232 respectively extend along the third direction D3 and are spaced apart from each other along the second direction D2. The air gaps 232 can be disposed on opposite sides of the first electrode 2121, the second electrode 2122 and the third electrode 2123 as a whole, and disposed between the first electrode 2121, the second electrode 2122 and the third electrode 2123. For example, the air gaps 232 may be disposed between the first electrode 2121 and the third electrode 2123, and between the second electrode 2122 and the third electrode 2123 (the present invention is not limited thereto). In the present embodiment, the number of air gaps 232 is 16, but the invention is not limited thereto. The first electrode 2121 to the third electrode 2123 are separated from the air gaps 232 by, for example, a dielectric material 260. Regions of the air gaps 232 projected on the substrate 110 along the first direction D1 (for example, the vertical direction) is disposed between regions of the first gate structure 2361 and the second gate structure 2362 projected on the substrate 110 along the first direction D1 (for example, the vertical direction). In other words, the air gaps 232 may not overlap the first gate structure 2361 and the second gate structure 2362 in the first direction D1.

According to the present embodiment, the semiconductor test structure 20 may further include an intermediate dielectric layer IMD. The intermediate dielectric layer IMD covers the first gate structure 2361, the second gate structure 2362 and the lower dielectric layer ILD, and is disposed between the first gate structure 2361, the second gate structure 2362 and the first conductive layer 212. That is, the air gaps 232 and the first conductive layer 212 may be disposed on the intermediate dielectric layer IMD. In some embodiments, the lower dielectric layer ILD, the intermediate dielectric layer IMD, and the dielectric material 260 may be formed of the same material, or may be different materials.

In a comparative example A, the semiconductor test structure is partially similar to the semiconductor test structure 10 of the present invention. The difference between the comparative example A and the semiconductor test structure 10 is that the semiconductor test structure of comparative example A does not include an air gap, does not include separate first gate structure and second gate structure, but includes an integral gate structure. The semiconductor test structure 10 according to the embodiment of the present invention may have a heating efficiency (i.e., used for reliability testing of electron migration, EM test) similar to that of comparative example A, for example, 300° C. to 500° C. In a comparative example B, the semiconductor test structure is partially similar to the semiconductor test structure 20 of the present invention. The difference between the comparative example B and the semiconductor test structure 20 is that the semiconductor test structure of comparative example B does not include an air gap, does not include separate first gate structure and second gate structure, but includes an integral gate structure. The semiconductor test structure 20 according to the embodiment of the present invention may have a heating efficiency similar to that of comparative example B (i.e., used for reliability testing of inter-metal dielectrics, IMD test), for example, 100° C. to 300° C.

The semiconductor test structures 10 and 20 of the present invention can be applied to any semiconductor device including an air gap, such as an RF SOI (radio frequency silicon-on-insulator) with an air gap (the present invention is not limited thereto). By building a semiconductor test structure into a semiconductor device, a fast monitoring method of the semiconductor device (for example, through EM/IMD test) can be provided to monitor whether the reliability of the semiconductor device meets expectations.

The semiconductor test structures 10 and 20 of the present invention can be applied to predict the failure (Time To Failure) of products for customers with different usage requirements (such as different current densities, temperatures and other requirements), and the test results can be obtained within a short time (for example, 3 days) can be completed.

The semiconductor test structure (e.g. 10 and 20) of the present invention can provide early process monitoring judgment. If there is a change in the manufacturing process, the semiconductor test structure of the present invention can be used directly in the clean room to test whether there is a risk of abnormality in the product at the wafer level in advance. There is no need to package the wafer before testing, which can save cost and time for packaging, with excellent market benefits. Furthermore, the method for wafer-level reliability testing takes less testing time and requires lower costs than the method for post-package reliability testing.

As mentioned above, the present invention provides a semiconductor test structure (such as 10 and 20), wherein the semiconductor test structure (such as 10 and 20) includes an air gap (such as 132 and 232), so compared to a semiconductor test without an air gap, the semiconductor test structure of the present invention (such as 10 and 20) can have lower capacitance, so it can meet the requirements of advanced semiconductors for reducing capacitance. Moreover, in the semiconductor test structure (such as 10 and 20), regions of the air gaps (such as 132 and 232) projected on the substrate (such as 110) along the first direction is between regions of the first gate structure (such as 1361 and 2361) and the second gate structure (such as 1362 and 2362) projected on the substrate along the first direction. The first gate structure (such as 1361 and 2361) and the second gate structure (such as 1362 and 2362) not only facilitate the reliability testing, but also meet the requirements of the semiconductor devices produced by the advanced process.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor test structure, comprising:
a substrate;
a first gate structure and a second gate structure, stacked on the substrate along a first direction, respectively extending along a second direction and spaced apart from each other along a third direction, wherein the first direction, the second direction and the third direction are different from each other;
a first conductive layer, stacked on the substrate along the first direction, wherein the first conductive layer comprises a first electrode and a second electrode, the first electrode extends along the second direction, and at least a portion of the second electrode extends along the second direction; and
at least one air gap, stacked on the substrate along the first direction and extending along the second direction, wherein the at least one air gap is disposed between the first electrode and the second electrode, and a region of the at least one air gap projected on the substrate along the first direction is disposed between regions of the first gate structure and the second gate structure projected on the substrate along the first direction.

2. The semiconductor test structure according to claim 1, further comprising
a diffusion layer and a contact structure stacked on the substrate along the first direction, wherein the first electrode, the contact structure and the diffusion layer are electrically connected.

3. The semiconductor test structure according to claim 1, wherein the at least one air gap comprises a first air gap and a second air gap, and the first electrode is disposed between the first air gap and the second air gap.

4. The semiconductor test structure according to claim 3, wherein the second electrode comprises two first portions extending along the second direction and two second portions extending along the third direction, the two first portions are spaced apart from each other along the third direction, the two second portions are spaced apart from each other along the second direction, and the two first portions are connected to the two second portions.

5. The semiconductor test structure according to claim 4, wherein the second electrode surrounds the first air gap, the first electrode and the second air gap.

6. The semiconductor test structure according to claim 1, wherein a material of the first gate structure and the second gate structure comprises polysilicon.

7. The semiconductor test structure according to claim 1, wherein the first gate structure and the second gate structure are separated by a lower dielectric layer.

8. A semiconductor test structure, comprising:
a substrate;
a first gate structure and a second gate structure, stacked on the substrate along a first direction, respectively extending along a second direction and spaced apart from each other along a third direction, wherein the first direction, the second direction and the third direction are different from each other;
a first conductive layer, stacked on the substrate along the first direction, wherein the first conductive layer comprises a first electrode, a second electrode and a third electrode spaced apart from each other; and
a plurality of air gaps, stacked on the substrate along the first direction and respectively extending along the third direction, wherein the air gaps are disposed between the first electrode, the second electrode and the third electrode, and regions of the air gaps projected on the substrate along the first direction are disposed between regions of the first gate structure and the second gate structure projected on the substrate along the first direction.

9. The semiconductor test structure according to claim 8, wherein the first electrode comprises a first main body portion and a plurality of first branch portions connecting to the first main body portion, and the first branch portions are spaced apart from each other; the second electrode comprises a second main body portion and a plurality of second branch portions connecting to the second main body portion, and the second branch portions are spaced apart from each other; the third electrode comprises a third main body portion and a plurality of third branch portions connecting to the third main body portion; the first main body portion, the second main body portion and the third body portion extend along the second direction, respectively; the first branch portions, the second branch portions and the third branch portions extend along the third direction, respectively.

10. The semiconductor test structure according to claim 8, wherein a material of the first gate structure and the second gate structure comprises polysilicon.

11. The semiconductor test structure according to claim 8, wherein the first gate structure and the second gate structure are separated by a lower dielectric layer.
